(19) United States
(12) Patent Application Publication
(10) Pub. No.: US 2025/0133390 A1
(43) Pub. Date: Apr. 24, 2025

(54) CELLULAR DEVICE INTERROGATION AND MANAGEMENT SYSTEM

(71) Applicant: MDESS, LLC, Beavercreek, OH (US)

(72) Inventors: Je'an Nicholas KORBIS, Adelaide (AU); Jeremy BAILEY, Martinez, GA (US)

(21) Appl. No.: 18/489,599

(22) Filed: Oct. 18, 2023

(51) Int. Cl. H04W 8/22; G01R 29/08; H04W 8/18

(52) U.S. Cl. CPC H04W 8/22; G01R 29/0821; H04W 8/183

(57) ABSTRACT

Aspects for verifying an identification of a cellular device are disclosed. In one such aspect, a method for managing cellular devices may include: receiving a cellular device in an RF containment space configured to provide an electronically isolated environment by blocking electromagnetic waves or radio frequency (RF) wave; providing, on a display, a graphical user interface (GUI); transmitting one or more cellular network signals configured to emulate at least one base station of a telecommunication carrier to cause the cellular device to initiate connecting to a network set up by a virtual base station coupled to the RF containment space; in response to the cellular device attempting to gain access to the network, obtaining device information from the cellular device placed in the RF containment space via the one or more cellular network signal; and extracting and storing identification information from the device information in the log.

### BACKGROUND

### Technical Field

The present disclosure generally relates to communication systems, and more particularly, to identification, registration, and management of telecommunication devices within a secured facility.

### Introduction

The use of contraband wireless devices, including cellular devices, tablets, etc., by users at a secured facility remains an ongoing problem. Sometimes these calls, texts or social media transmissions, etc., are innocuous policy violations at the secured facility. In other cases, the use of contraband wireless devices may constitute state or federal crimes. A significant number of calls and texts based on contraband devices, however, are more sinister. For example, in the context of correctional facilities, contraband wireless devices have been used by inmates to order the deaths of individuals, facilitate smuggling of controlled substances and weapons into the facility, set up means for escape attempts, initiate organized gang violence, run organized crime outside of the correctional facilities, etc.

In addition, wireless devices may also be used inside a secured facility for espionage purposes such as recording or capturing confidential information inside the secured facility. For example, an IT employee may go into a secured facility and use their wireless device to steal confidential information or trade secrets. Accordingly, it is important to properly identify and manage wireless devices that are entering and leaving a secured facility.

Conventional attempts to address contraband devices inside a secured facility include contracting a specialized firm to take up long-term or permanent residence at the secured facility. The contractor may include its own facility-specific telecommunications network and base station to regulate all voice and data transmissions to and from the facility. Ideally, the antennas and network components are positioned such that all communications, authorized or otherwise, are routed through this internal network to confirm they are legitimate. The internal network may block transmissions from suspicious or confirmed contraband devices, and may gather information from the transmissions for investigative purposes.

One problem with this implementation is the potentially exorbitant cost to the facility of running the internal network on a 24/7 basis. Another problem is the network itself. The antennas' transmissions can “bleed” out of the facility, inadvertently blocking legitimate transmissions from citizens that happen to be driving by the facility, for example. The opposite problem may occur where the antenna power is reduced to avoid bleeding but where the reduction is sufficient to enable contraband devices to access external base stations, and hence bypass the very protections put in place to prevent this activity.

It is therefore important to develop new techniques that identify, register, and track the entry and exit of wireless devices in a secured area an easy and reliable manner.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

Conventional solutions to identifying, registering, and or tracking contraband wireless devices inside a secured facility include retaining a contractor firm to situate itself at the facility and set up a “managed access system” (MAS) including an intermediary wireless network having base stations, monitoring equipment, etc. The MAS is a system that deploys a secure cellular umbrella over a specified area within the bounds of a secured facility to either permit or to interface with transmissions of cellular devices within the facility. For purposes of this disclosure, a MAS can include either a mobile or a fixed network, or a combination of both, including any cellular network for gathering relevant data. The base station's antennas are directed and powered to cover the facility grounds. Inmates may often attempt to possess and use contraband wireless devices including cellular telephones, disposable phones, and even tablets and personal computers (PCs) over the wireless network for voice calls, texts, instant messages, VOIP transmissions, and the like. Ideally, the MAS authorizes legitimate calls from pre-authorized phones, etc. and intercepts unauthorized transmissions. The MAS may include a central facility on the premises using servers to gather and process information about the unauthorized transmissions, to add devices to the contraband list, and to facilitate investigative efforts of the facility staff into related illegal activities.

This present solution can be prohibitively expensive. For one, the facility must be monitored on a 24/7 basis. The maintenance of the equipment and contracted staff likely burdens the allotted budgets of these facilities. Technical challenges also must be addressed. Examples include where the antennas from the base station at the facility inadvertently “bleed” to regions outside the facility to prevent legitimate calls from being intercepted or cut off. Similarly, the facility may include spotty regions where inmates can access external base stations using contraband devices. The problems are exacerbated in an urban environment, where the potential number of networks and individuals near the facility increase.

Aspects of the present disclosure overcome the above-stated problems and other shortcomings with this approach.

In an aspect of the disclosure, a method, system, and apparatus are provided. The method for managing cellular devices may include receiving a cellular device in an RF containment space configured to provide an electronically isolated environment by blocking electromagnetic waves or radio frequency (RF) waves such that the cellular device is electronically isolated from outside when the cellular device is placed inside the RF containment space. The method may also include providing, on a display, a graphical user interface (GUI) for inputting information, displaying information associated with the cellular device, or viewing a log. The method may also include transmitting, using the one or more internal antennas, one or more cellular network signals configured to emulate at least one base station of a telecommunication carrier to cause the cellular device to initiate connecting a network setup by a virtual base station coupled to the RF containment space. The method may further include, in response to the cellular device attempting to gain access to the network, obtaining device information from the cellular device placed in the RF containment space via the one or more cellular network signals. The method may further include extracting and storing identification information from the device information in the log.

In another aspect of the disclosure, a system is provided. The system for managing cellular devices may include a box configured to provide an electronically isolated environment by blocking electromagnetic waves or radio frequency (RF) waves such that a cellular device is electronically isolated from outside the box when placed in the box, where the box may comprise one or more internal antennas, one or more scanning antennas, and one or more processors. The apparatus may further include a display, a memory configured to store at least a profile database and a log, and a processing system. The processing system may be configured to: provide, on the display, a graphical user interface (GUI) for inputting information when generating the profile and displaying the profile of the cellular device, generate a virtual base station configured to emulate at least one base station of a telecommunication carrier, wherein the virtual base station is coupled to the box, transmit, using the one or more internal antennas, one or more cellular network signals configured to emulate at least one base station of a telecommunication carrier to cause the cellular device to attempt to connect to a network set up by the virtual base station, in response to the cellular device attempting to gain access to the network, obtain device information from the cellular device placed in the box via the one or more cellular network signal, and extract and store identification information from the device information in the log.

In another aspect of the disclosure, an apparatus is provided. The apparatus for managing cellular devices in a secured facility may include a box configured to provide an electronically isolated environment by blocking electromagnetic waves or radio frequency (RF) waves such that a cellular device is electronically isolated from outside the box when placed in the box, where the box may comprise one or more internal antennas, one or more scanning antennas, and one or more processors. The apparatus may further include a display, a memory configured to store at least a profile database and a log, and a processing system. The processing system may be configured to: provide, on the display, a graphical user interface (GUI) for inputting information when generating the profile and displaying the profile of the cellular device, generate a virtual base station configured to emulate at least one base station of a telecommunication carrier, wherein the virtual base station is coupled to the box, transmit, using the one or more internal antennas, one or more cellular network signals configured to emulate at least one base station of a telecommunication carrier to cause the cellular device to attempt to connect to a network set up by the virtual base station, in response to the cellular device attempting to gain access to the network, obtain device information from the cellular device placed in the box via the one or more cellular network signal, and extract and store identification information from the device information in the log.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

FIG. 1 is a diagram illustrating an example of an identification system deployed inside a secured facility for identifying and/or registering cellular devices according to an embodiment.

FIG. 2 is a call flow diagram of an example identification process between an identification system and a cellular device placed within a shielded box according to an embodiment.

FIGS. 3A-B are call flow diagrams of example identification processes between an identification system and a cellular device according to an embodiment.

FIG. 4 is an example of a dashboard UI according to some embodiments.

FIG. 5 is an example of a profile UI according to some embodiments.

FIG. 6 is an example of a check in/check log according to some embodiments.

FIG. 7 is an example of a Capture, Control, and Intelligence (C2I) Web GUI according to some embodiments.

FIGS. 8-11 are flowchart examples of an example method of identifying and/or managing cellular devices using an identification system according to an embodiment.

FIG. 12 is a diagram illustrating an example of a hardware implementation for an apparatus according to an embodiment.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of telecommunication systems will now be presented with reference to various apparatus and methods. These apparatus and methods will be described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), Software defined Radio (SDR), Power Amplifiers (PA), state machines, gated logic, discrete hardware circuits, and other suitable hardware configured to perform the various functionality described throughout this disclosure. One or more processors in the processing system may execute software. Software shall be construed broadly to mean instructions, instruction sets, computer-executable code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more example embodiments, the functions described may be implemented in hardware, software, or any combination thereof. If implemented in software, the functions may be stored on or encoded as one or more instructions or computer-executable code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer-executable code in the form of instructions or data structures that can be accessed by a computer.

As used herein, the terms “cellular device,” “telecommunication carrier devices,” “wireless devices”, “user equipment” (UE), and “base station” are not intended to be specific or otherwise limited to any particular Radio Access Technology (RAT), unless otherwise noted. In general, a cellular device, telecommunication carrier device, wireless device, or UE may be any wireless communication device (e.g., a mobile phone, router, tablet computer, laptop computer, tracking device, wearable (e.g., smartwatch, glasses, augmented reality (AR)/virtual reality (VR) headset, etc.), vehicle, Internet of Things (IoT) device, etc.) used by a user to communicate over a wireless communication network. A UE may be mobile or may (e.g., at certain times) be stationary, and may communicate with a Radio Access Network (RAN). As used herein, the terms “cellular device,” “mobile device”, “telecommunication carrier device.” “wireless terminal”, or “UE” may be referred to interchangeably as an “access terminal” or “AT”, a “client device”, a “wireless device,” a “subscriber device,” a “subscriber terminal”, a “subscriber station,” a “user terminal,” a “mobile terminal,” a “mobile station”, or variations thereof. Generally, UEs can communicate with a core network via a RAN, and through the core network the UEs can be connected with external networks such as the Internet and with other UEs. Of course, other mechanisms of connecting to the core network and/or the Internet are also possible for the UEs, such as over wired access networks, wireless local area network (WLAN) networks (e.g., based on IEEE 802.11, etc.) and so on.

A base station may operate according to one of several RATs in communication with UEs depending on the network in which it is deployed, and may alternatively referred to as an access point (AP), a network node, a NodeB, an evolved NodeB (eNB), a New Radio (NR) Node B (also referred to as gNB or gNodeB), etc. In addition, in some systems, a base station may provide purely edge node signaling functions while in other systems it may provide additional control and/or network management functions. A communication link through which UEs can send signals to a base station is called an uplink (UL) channel (e.g., a reverse traffic channel, a reverse control channel, an access channel, etc.). A communication link through which the base station can send signals to UEs is called a downlink (DL) or forward link channel (e.g., a paging channel, a control channel, a broadcast channel, a forward traffic channel, etc.).

The term “base station” may refer to a single physical transmission-reception point (TRP) or to multiple physical TRPs that may or may not be co-located. For example, where the term “base station” refers to a single physical TRP, the physical TRP may be an antenna of the base station corresponding to a cell of the base station. Where the term “base station” refers to multiple co-located physical TRPs, the physical TRPs may be an array of antennas (e.g., as in a multiple-input multiple-output (MIMO) system or where the base station employs beamforming) of the base station. Where the term “base station” refers to multiple non-co-located physical TRPs, the physical TRPs may be a distributed antenna system (DAS) (a network of spatially separated antennas connected to a common source via a transport medium) or a remote radio head (RRH) (a remote base station connected to a serving base station). Alternatively, the non-co-located physical TRPs may be the serving base station receiving the measurement report from the UE and a neighbor base station whose reference RF signals the UE is measuring. Because a TRP is the point from which a base station transmits and receives wireless signals, as used herein, references to transmission from or reception at a base station are to be understood as referring to a particular TRP of the base station.

An “RF signal” comprises an electromagnetic wave of a given frequency that transports information through the space between a transmitter and a receiver. As used herein, a transmitter may transmit a single “RF signal” or multiple “RF signals” to a receiver. However, the receiver may receive multiple “RF signals” corresponding to each transmitted RF signal due to the propagation characteristics of RF signals through multipath channels. The same transmitted RF signal on different paths between the transmitter and receiver may be referred to as a “multipath” RF signal. Various aspects of the present disclosure describe identifying, verifying, and registering an identify of cellular devices using an identification system and a simple UI. For example, the identification system for cellular devices may be deployed at a secured facility such as an inmate correctional facility, schools, psychiatric hospitals, government buildings, or classified laboratories or buildings. Conventional techniques rely on a contracting firm placing a permanent network at a secured facility. As an example, a base station and related server system is established as part of a managed access system (MAS) deployed at a correctional facility. One significant disadvantage with this approach is the potentially exorbitant expense to the facility to have a permanent firm performing this cellular contraband regulation 24 hours a day, seven days a week for a possibly indefinite period. Additional shortcomings relate to the problems that occur when the network inadvertently “bleeds” into the surrounding area, resulting in civilians' cellular equipment being affected by the prison network. If the contracting firm attempts to fix this problem (particularly in an urban environment involving other base stations in the proximity of the facility) by reducing the transmission and receive power of the on-site base station(s), then it may become possible for inmates to reach external base stations using contraband phones. The inmates may then altogether bypass the restrictions in place.

According to one aspect of the disclosure, an apparatus (e.g., telecommunications recordings and collection equipment (TRACE) box or identification box) may contain a base station or deploy a virtual base station to emulate a base station of a telecommunication carrier in order to extract electronic identifiers from a cellular device. In the aspects disclosed herein, the apparatus may include a RF containment space (e.g., shielded box) for receiving a cellular device such that the cellular device is electronically isolated from an outside environment when placed inside the RF containment space. Once the cellular device is electronically isolated from the outside environment, the apparatus interrogates the cellular device for its electronic identifiers by forcing the cellular device to connect to a network set up by the base station or virtual base station. This causes the cellular device to attempt to connect to the network and, in the connection process, transmit its electronic identifiers to the apparatus. In addition, the apparatus may also determine whether the cellular device in the box is a known device or a unknown device by comparing the obtained electronic identifiers from the cellular device with a database of electronic identifiers from known devices (e.g., registered devices).

The apparatus provides a simple and reliable way to identify, check in, check out, and/or register cellular devices using their electronic identifiers. Since the electronic identifiers cannot be easily falsified or manipulated, a user of the apparatus can easily and quickly check and verify the identity of and/or create profiles for any cellular devices using the electronic identifiers by simply placing the cellular device in the RF containment space and operating a graphical user interface (GUI). Additionally, the apparatus is very simple to use because all an operator of the apparatus has to do is to place the cellular device inside of the RF containment space and press a button to operate the identification process. This makes the identification process virtually fool proof. This also eliminates the need for a contractor to actively monitor and detect wireless devices, as compared to conventional solutions. This may result in a large cost savings to the secure facility. Also, the concerns of “bleeding” spurious, interfering transmissions outside the facility may largely be eliminated because the contractor no longer has a need for a base station at the facility.

Furthermore, the identification system may be coupled to a cellular device registration, logging, and/or monitoring system such that when a cellular device is placed within the RF containment space, the logging or monitoring system can automatically extract electronic identifiers from the cellular device and log the cellular device. This makes it so that the identity of a cellular device cannot be easily manipulated or falsified by an operator when creating a profile for the cellular phone or a log entry for the cellular device.

It should be noted that, while the entity managing the data collection and subsequent duties is referenced herein as a “operator,” “contractor.” or “contracting firm” purely for convenience, this reference is not intended to have any legal significance, and is not intended to limit the disclosure in any way. Thus, for example, the operator or contractor need not be contracted by the carrier to perform the activities herein.

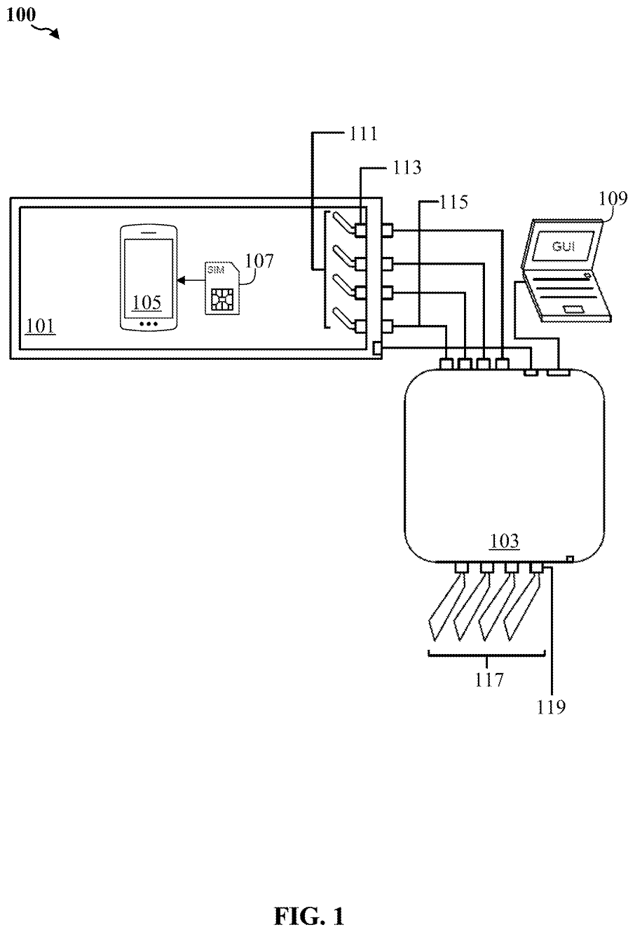

FIG. 1 is a diagram illustrating an example of an identification system 100 that may be deployed to identify cellular devices. The purpose of the identification system is to easily and reliably identify and verify the identity of cellular devices using their electronic identifiers by creating a condition within an RF containment space (e.g., an enclosed and shielded box) that causes the cellular devices to connect to a base station provided by the identification system and then extract wireless identifiers from the cellular devices. The extracted wireless identifiers may then be used to further extract an identification information of the cellular devices for identification, registration, tracking, and/or logging purposes.

In some examples, the identification system 100 may be strategically placed near the entrances and exits of a secured facility in order to manage cellular devices that enter and leave the secured facility. In some examples, the identification system 100 may be mobile or portable (i.e., capable of being moved through different geographical positions). It should be noted that FIG. 1 is not drawn to scale. Rather, its components are minimized to avoid unduly obscuring the concepts of the disclosure.

As shown FIG. 1, the identification system 100 comprises at least a shielded box 101 (e.g., RF containment space) configured to create an RF containment space or block electromagnetic waves, one or more processors, and, optionally, a base transmission station (base station) 103 and/or display 109 from an external device or computing device. The identification system 100 has a shielded box that is configured to receive at least one cellular device 105 and uses one or more internal antennas 111 to emulate a base station of a telecommunication carrier (e.g., Verizon, T-Mobile, AT&T, or the like) by transmitting network parameters to the at least one cellular device 105, which causes a communication between the at least one cellular device 105 and the base station. Upon activation of the identification system 100, the at least one cellular device 105 will attempt to connect to a network set up by the base station 103 and, in turn, transmit an electronic identifier to the identification system 100 while in the process of connecting with the network. The identification system 100 may further derive a make, model, or manufacturer of the cellular device 105 from the electronic identifiers. This ensures that the identity of the cellular device 105 is verified because the electronic identifiers are unique to each cellular device 105 and difficult to manipulate or falsify.

The shielded box 101 comprises one or more internal antennas 111, internal SubMiniature version A (SMA) connectors 113, and, optionally, a status indicator (not pictured). The shielded box 101 is configured to provide an electronically isolated environment by blocking electromagnetic waves or RF waves. This means that when a cellular device 105 is placed inside the shielded box 101, the cellular device 105 is electronically isolated from the outside environment (e.g., outside the box). The shielded box 101 should be isolated to determine with certainty that the electronic identifiers extracted from the cellular devices 105 belong to the cellular devices 105 that are placed inside the shielded box 101. If the shielded box 101 was not isolated from the outside environment, then the identification system 100 would not be able to say with certainty that the electronic identifiers belong to the cellular device 105 placed inside the shielded box. In addition, the shielded box 101 is isolated to stop other carrier signals from interfering with the cellular devices 105 inside the shielded box 101 and to ensure that the base station 103 is not communicating with other devices outside of the shielded box 101. In some examples, the shielded box 101 may be a Faraday cage. In some examples, the identification system 100 may also include a status indicator, which may be a LED, a stack light, a display, or the like.

In some examples, the shielded box 101 may be electrically and physically tamperproof. Since the shielded box 101 may be deployed in a secured facility such as a correctional facility, the identification system 100 should be ruggedized and tamperproof to prevent the identification system 100 from being sabotaged. For instance, the identification system 100 may contain tamperproof screws and/or have screwing mechanisms made out of titanium or stainless steel. In some examples, the interior of the identification system 100 may be constructed out of aluminum and the exterior box may be made out of a black polycarbonate.

Optionally, the identification system 100 may include a base station (e.g., transmitter-receiver) 103. The base station 103 comprises one or more scanning antennas 117 and one or more external SMA connector 119. In some examples, the base station 103 is connected to the one or more internal antennas 117 via RF cables 115. The one or more scanning antennas 117 are configured to identify networks in an area of interest in order to determine transmission for inside the shielded box 101. In some examples, the identification system 100 comprises one or more processors configured to implement a virtual base station. In some examples, the base station 103 may be coupled via a backhaul connection to additional network equipment, including server and gateway.

In some examples, the identification system 100 may include a memory configured to store identifying data or electronic identifiers of identified wireless devices, one or more base stations and one or more antennas, a processing system to emulate a base station to transmit a signal to wireless devices and to carry out various computation functions of the system, and a housing that encompasses the device to prevent tampering or sabotage. The one or more base stations typically carries out the various transmission and reception functions of the identification system 100. The processing system carries out various computation functions of the identification system 100.

Data collection during interrogation. The raw data collected by the identification system 100 from the transmitting cellular devices 105 may include metadata included with various message. Other relevant identifying data that may be transmitted from different wireless devices includes IMSI (International mobile subscriber identity), IMEI (International mobile equipment identity), GUTI (Globally unique temporary ID), SMS (Short message service), and other relevant data not limited to this list.

An IMSI is a unique number that is attached to a SIM card 107 and is used to identify the subscriber and services assigned to the subscriber. Accordingly, if a user transfer their SIM card 107 from one cellular device to another cellular device, the IMSI number from the previous cellular device will be carried over to the replacement cellular device that has been inserted with the SIM card.

An IMEI is a unique identifier for a cellular device that is the IMEI is attached to and is used to identify the cellular device 105. Since IMEI numbers are unique to a cellular device and cannot be easily changed, the IMEI numbers are useful in tracking and recovering lost or stolen phones. In addition, there is a global registry that contains all IMEI numbers such as Equipment Identification Register (EIR) that can be used to identify the cellular device and, therefore, identify an owner of the cellular device.

The equipment Identity Register (EIR) is a network database that stores lists of IMEI numbers. This database is used to manage valid IMEIs on the network so that stolen cellular devices or cellular devices of the wrong type would not be able to connect to the network. When a cellular devices is switched on, its unique IMEI number is transmitted to the network and checked against the EIR, which determines whether the cellular device can log onto the network to initiate and receive calls.

When a cellular device attaches to a network, the cellular device sends a signal to the network containing both IMSI and IMEI information. The IMSI is used for location update of the VLR/HLR registers, whereas the IMEA is used for checking of invalid equipment in the EIR repository. In addition, the cellular device will register the IMEI on the network along with the IMSI (if a SIM card is inserted). In some examples, the IMEI and IMSI is also being used by some applications and smartphone Operating systems for identification and is being tracked. For example, a mobile operator subscriber log may store the IMEI along with the IMSI and their subscriber information database. If a user uses a pre-paid anonymous SIM card (e.g., anonymous IMSI but with a known IMEI), the mobile operator may see that the cellular device belonged to a particular person if the person used that cellular device before with a different SIM (e.g., different IMSI but same known IMEI).

There may be several different methods of obtaining electronic identifiers from a cellular device by causing the cellular device to perform an attach process to a network provided by a base station of the identification system. For example, the cellular device must be placed inside the shielded box in order to electronically isolate the cellular device from an outside environment and cause the shielded box to transmit, using one or more internal antennas, cellular network signals configured to emulate a base station of a telecommunication carrier to cause the cellular device to attempt to connect to the network provided by the base station. It should be noted that there are several methods for a cellular device to attach to different RATs, but a few specific attach procedures will be explained below for illustrative purposes only.

When a cellular device has been enticed to register with an identification system, the cellular device may be interrogated for its IMSI. Many interrogation techniques can be derived directly from a reading of the cellular standard. In the case of Global System for Mobile communication (GSM), Universal Mobile Telecommunications Systems (UMTS), fourth generation long-term evolution (4G/LTE), fifth generation New Radio (NR), and 6G wireless device, the International Standard Mobile Identifier (IMSI), the Temporary Mobile Standard Identifier (TMSI), and the equipment electronic serial number (IMEI), the LTE Globally Unique Temporary ID GUTI, Subscription Concealed Identifier (SUCI) can be queried. For example, GUTI comprises of two main components, Globally Unique Mobility Management Entity Identifier (GUMMEI), which uniquely identifies a MME, and Mobile Temporary Mobile Subscriber Identity (M-TMSI), which identifies a user. As another example, SUCI is a unique identifier designed to protect the privacy of the subscriber's identity and is generated by the UE using an Elliptic Curve Integrated Encryption Scheme (ECIES)-based protection scheme.

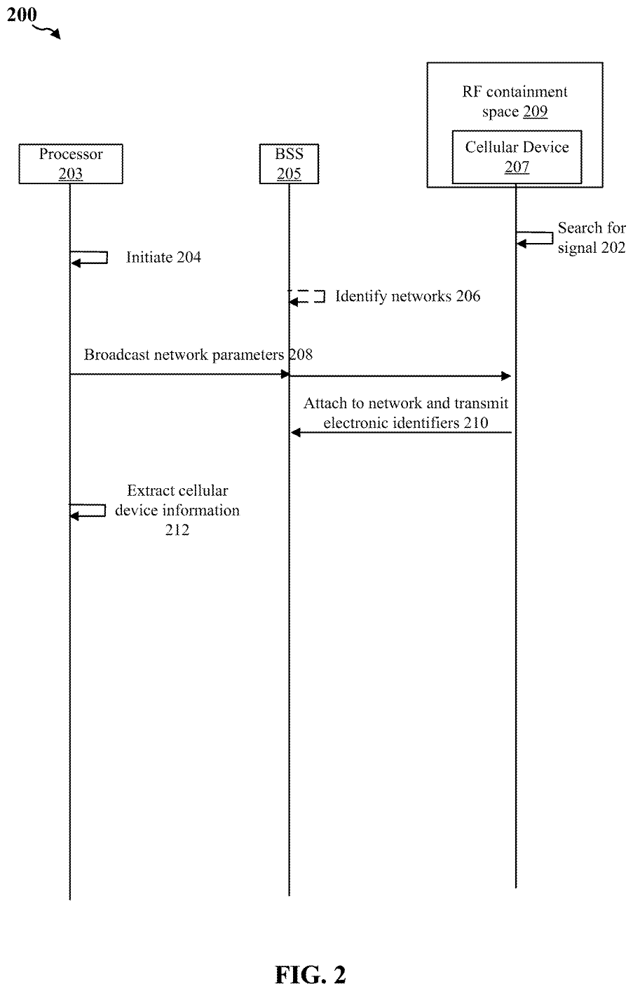

FIG. 2 is a call flow diagram of an example identification process between an identification system 200 and a cellular device 207 placed within a shielded box 209 (e.g., containment space) according to an embodiment. Optional aspects are illustrated in dashed lines.

Specifically. FIG. 2 shows an identification process for a wireless device using a general Attach Procedure. The Attach Procedure may be different depending on which RAT network the cellular device is attempting to attach to. However, the overall goal of the Attach Procedure for each RAT is the same, which is to register a cellular device 301 to the network such that the cellular device 301 is able to register with the network to receive services. Accordingly, the identification system will invoke the Attach Procedure to obtain an electronic identifier, via an update location, from the cellular device 301.

At step 202, the cellular device 207 is placed in a shielded box 209 such that the cellular device 207 is electronically isolated from an outside environment and will search for a network to connect to.

At step 204, the processor 203 will initiate the identification process and emulate at least one base station of a telecommunication carrier to cause the cellular device 207 to attempt to connect to a network set up by the base station 205 when searching for a network.

Optionally, at step 206, the base station 205 will identify the networks in the area and decide the best transmissions to transmit inside the shielded box 209. The base station 205 may scan the networks periodically to determine whether there has been any changes in the RF footprint for commercial carriers. For example, the scanning process may be performed once a month.

At step 208, the processor 203 will cause internal antennas in the shielded box 209 to broadcast network parameters to cause the cellular device 207 to send a request to connect to a network setup by the base station 205. In some examples, the one or more cellular signal may be transmitted on one or more RAT to cause the cellular device 207 to attempt to connect to the network setup by the base station 205.

At step 210, the cellular device 207 will attach to the network and transmit its electronic identifiers as a result of attempting to connect to a network provided by the base station 205. As examples, a few different ways that the network may obtain electronic identifiers from the cellular device include through an IMSI attach, or location updating. Here, the electronic identifier will generally include at least a IMSI, which may be used as an electronic identifier of the cellular device 207. The IMSI is a number that uniquely identifiers every user of a cellular network. It is stored as a 64-bit field and is sent by the cellular device to the network.

At step 212, the processor 203 may extract additional cellular device information from the electronic identifier. As an example, the processor 203 may extract a make, model, or manufacture of the cellular device 207 using a Type Allocation Code (TAC) according to the IMEI of the cellular device.

As discussed above, there are several different methods for a network to obtain electronic identifiers from a cellular device.

To make it possible for a mobile subscriber to receive a call, the network must know where the cellular device is located. Accordingly, to keep the network updated on a location of the cellular device, the network system is informed by the cellular device on a regular basis. This process is called Location Updating. For example, the location update may occur in the following cases: (1) the cellular device detecting that it is in another location area (different location area code (LAC)) (e.g., when the cellular device is placed in a shielded box), or (2) the network requires the cellular device to perform location update at regular intervals.

Accordingly, the identification system may emulate a network provider and force the cellular device to transmit a location update process by placing the cellular device into a shielded box because once the cellular device is placed in the shielded box then the cellular device will be forced to perform a location update. There are three different types of location updates: normal, periodic registration, and IMSI attach/detach.

### Normal Location Updating

In normal location updating, the location is initiated by the cellular device when it detects that it has entered a new location area (e.g., placed in the shielded box). The cellular device then listens to the system information, compares the Location Area Identity (LAI) to the one stored in the cellular device on the SIM card (on BCCH channel if idle or SACCH channel if active) and detects whether it has entered a new location area or is still in the same location area. If the broadcast LAI differs from the one stored on the SIM card, the cellular device must perform a normal location update procedure.

First, the cellular device sends a channel request message including the reason for the access. Next, the message received by the base stations is forwarded to the BSC. The BSC allocates an SDCCH, if there is one idle, and tells the BTS to activate it. The cellular device is now told to tune to the SDCHH. Here, the cellular device send a location updating request message that contains the identity of the cellular device, the identity of the old location are and the type of updating. At this point, the identification system will know the identity of the cellular device through the IMSI and/or IMEI.

### Periodic Registration Location Updating

Periodic registration location may be used to reduce unnecessary paging of a cellular device that has left the coverage area (e.g., placed in a shielded box). First, the cellular device listens on the BCCH to specify if Periodic Registration Location Update is used in the cellular device. If periodic registration is used, the cellular device is told how often it must register. The frequency of periodical location update is controlled by the network, or according to the T3212 parameter. The T3212 is a decimal number within the range of 0 to 255 in the units of six minutes. For example, if the parameter is set to ten, then the cellular device must register every hour.

Both the cellular device and the MSC have the timer which controls the procedure. When the timer in the cellular device expires, the cellular device performs a location updating, type periodic registration. After that, the timers in the cellular device and MSC restart. The periodic registration timer is implemented in the cellular device, and will be reinitiated every time the cellular device returns to idle mode after being in dedicated mode.

### IMSI Attach/Detach:

The IMSI attach/detach operation is an action taken by a cellular device to indicate to the network that it has entered into idle mode/inactive state. When a cellular device is powered on, an IMSI and/or IMEI attach message is sent to the MSC/VLR.

An example of an attach procedure is a GSM attach procedure. When a GSM cellular device is placed inside the box, the base station will emulate a network provider because the GSM cellular device will try to connect to whatever base station is broadcasting at the highest signal strength. Since the GSM cellular device is electronically isolated into the box, the only base station that will be broadcasting a network is the base station provided by the identification system 100. Once the GSM cellular device has identified the base station as having the best (e.g., in this case, the only) signal strength, the GSM cellular device begins negotiating a connection to the base station. The base station will first ask the GSM cellular device to send its encryption capabilities. After this step, the base station transmits an Identity Request to the GSM cellular device to collect the IMSI of the GSM cellular device. The GSM cellular devices responds with its IMSI because the IMSI is stored on the SIM card, which was issued by a mobile carrier, and the phone network needs to identify that the owner/user of the GSM cellular device is in fact a paying customer (e.g., subscriber) associated with the mobile carrier.

The identification system 100 may invoke a GPRS Attach procedure by which a Mobile Station (MS) registers (e.g., connects) to a GPRS network set up by a base station of the identification system. During the GPRS Attach procedure, when the MS makes an attach procedure for the first time, the MS will identify itself to the network using an IMSI. In other words, the GPRS Attach procedure enables the network (e.g., identification system 100 from FIG. 1) to know about the identify and existence of a cellular device 301.

When an MS powers on within network coverage, it starts by scanning all frequencies within its allocated band (e.g., 124 for standard GSM). It measures the received power on each of these frequencies and places them in order. The MS then selects and listens on the strongest RF level carrier for a frequency correction burst which is transmitted on the control channel of a BCCH carrier. This is to initially achieve frequency synchronization with the transmitting base station.

Having achieved frequency synchronization, the MS listens on the SCH for frame synchronization information. The SCH channel provides frame timing, the current frame number and BSIC information.

Once frame synchronization is achieved, the MS starts to read and decode the additional information being transmitted on the BCCH. This includes the adjacent cell list, minimum received signal strength, the LAI and beacon frequencies from surrounding cells. The MS then continues to monitor the PCH for incoming call paging requests, sends periodic location updates and maintains a record of surround cell signal strengths. If the MS fails to detect either the FCCH or the SCH, it will reselect the highest RF carrier level from its measured list and repeats the detection process.

The MS sends a message to the BSS on the random access channel (RACH) requesting a channel allocation. The BSS responds with a “Immediate Assignment” message on the access grant channel (AGCH). This message assigns a SDCC channel to the MS.

On assignment of the SDCCH, the MS sends an IMSI attach message over the SDCCH to the MSC/VLR relayed via the BSS. This informs the MSC/VLR of the MS's IMSI. This information may also be updated in the HLR which provides subscriber profile data to the VLR if it does not already have it.

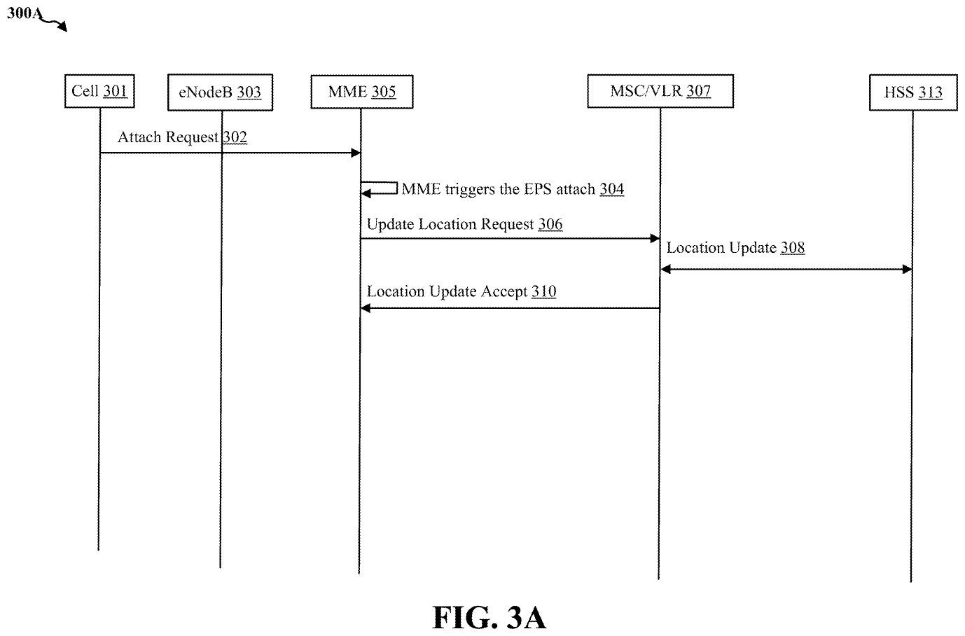

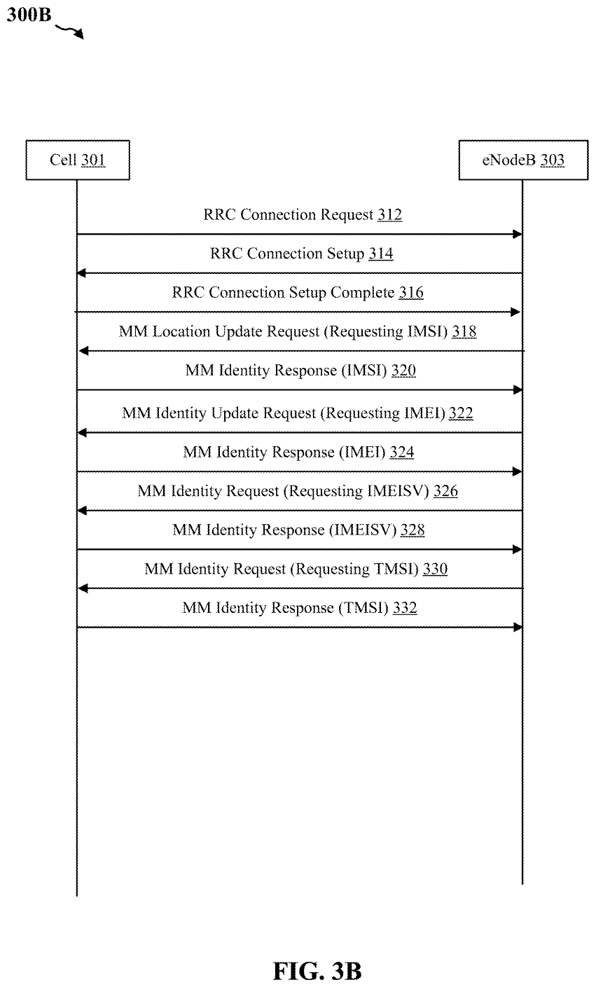

FIG. 3A is a call flow diagram of an example identification process between an identification system and a wireless device according to an embodiment. Specifically, example 300A from FIG. 3A shows an identification process for a wireless device using an Attach Procedure. The goal of the Attach Procedure is to register a cellular device 301 to the network such that the cellular device 301 is able to register with the network to receive services. Accordingly, the identification system will invoke the Attach Procedure to obtain electronic identifiers, via an update location, from the cellular device 301.

At step 302, the cellular device 301 sends an “Attach Request” to the Mobile Management Entity (MME) 305. This includes the GUTI of the cellular device 301 received from the last attach, and the Access Point Name (APN) that the cellular device 301 would like to connect to. At this point, the identification system may have already obtained an electronic identifier since the Attach Request contains the IMSI information of the cellular device 301.

At step 304, the MME 305 triggers an EPS attach.

At step 306, the MME 305 sends an update location request, which includes the MME ID of the MME 305, to the MSC/VLR 307.

At step 308, the HSS and the MSC/VLR 307 exchange location updates. This is done because the HSS 313 should always know which MME 305 is currently serving the cellular device 301. In addition, the HSS 313 provides the MME 305 with cellular device subscription information, including the PDNs that the cellular device 301 is allowed to access.

At step 310, the MSC/VLR 307 sends an location update accept 310 to the MME 305.

FIG. 3B is a call flow diagram of an example identification process between an identification system and a wireless device according to an embodiment. Specifically, example 300B from FIG. 3B shows an identification process for a wireless device using a LAC update timer.

At step 312, the cellular device 301 transmits a RRC connection request to the eNodeB 303. At step 314, the eNodeB 303 responds with a RRC connection Setup. At step 316, the cellular device 301 transmit a RRC connection setup complete.

At step 318, the eNodeB 303 transmits a MM location update request to request the IMSI of the cellular device 301.

At step 320, the cellular device 301 responds with an MM identity response which includes the IMSI. The IMSI is an electronic identifier that can be used to identify the cellular device 301.

At step 322, the eNodeB 303 transmits a MM identity request to request the IMEI of the cellular device 301. At step 324, the cellular device 301 responds with a MM identity response that includes the IMEI. The IMSI is another electronic identifier that can be used to identify the cellular device 301.

At step 326, the eNodeB 303 transmits a MM identity request to request the international mobile station equipment identity software version (IMEISV) of the cellular device 301. At step 328, the cellular device 301 responds with a MM identity response that includes the IMEISV. The IMEISV is a code that identifies the mobile phone and the version of its software.

At step 330, the eNodeB 303 transmits a MM identity request to request the temporary identification number (TMSI) of the cellular device 301. At step 332, the cellular device 301 responds with a MM identity response that includes the TMSI. The TMSI is a temporary identification number that is used in a GSM network instead of the IMSI to ensure the privacy of the mobile subscriber.

When the cellular device 301 sends the MM location update request, it also starts an LAC timer. The eNodeB 303 ignores this request. If the cellular device 301 does not receive a valid response to the MM location update request within a predetermined time, then the cellular device 301 may resend the MM location update request. This process is repeated a few times and then the cellular device 301 aborts the connection.

Thus, by sending a series of three MMI identity request immediately after the RRC connection is established and before the cellular device 301 aborts the connection, the eNodeB 303 can receive the MM Identity Response messages from the cellular device 301 without requiring integrity protection.

Once the identity information has been collected, the eNodeB3 03 rejects the location update request thus preventing the cellular device 301 from repeatedly trying to camp on the eNodeB 303.

Although there may be many different ways to obtain electronic identifiers such as obtaining a location update from a cellular device. It should be noted that this disclosure is not limited to the specific procedures to obtain electronic identifiers. Instead, the disclosure describes the specific procedures for illustrative purposes only.

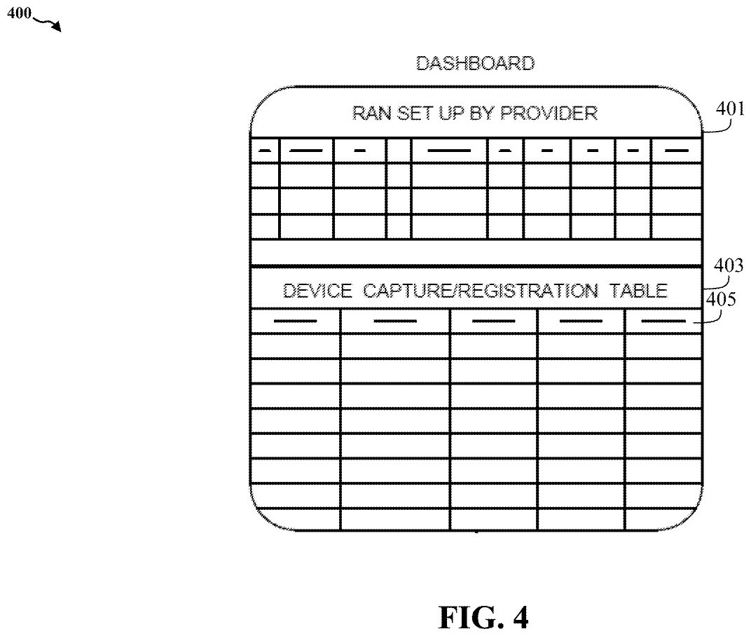

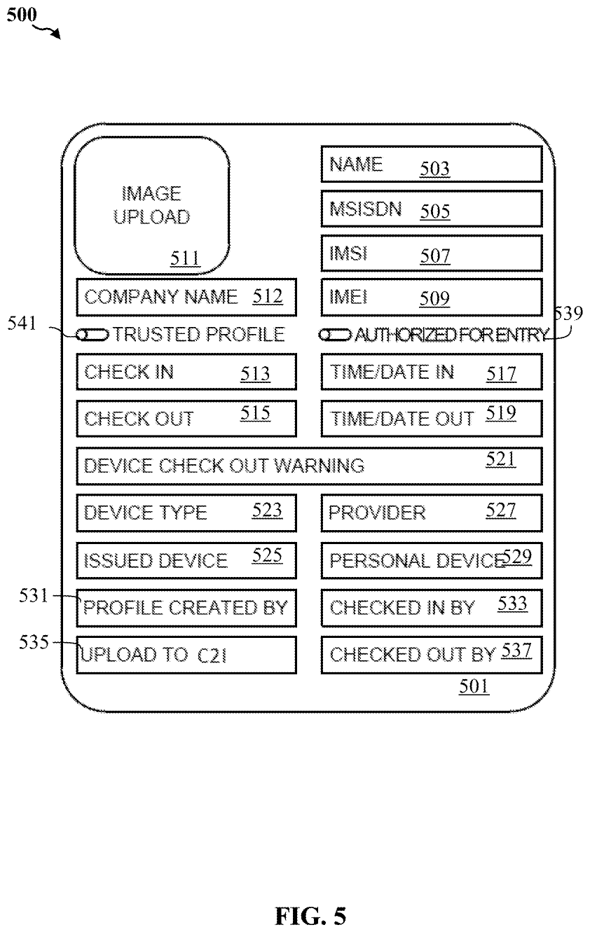

FIG. 4 is an example of a dashboard UI according to some embodiments. As shown in example 400, the dashboard UI may display a RAN set up table 401 and/or Device Capture/Registration Table 403 on either an external device or a display on the identification system. In some examples, the RAN set up table 401 lists all the different radio access networks and different telecommunication carriers emulated transmitted by the base station or virtual base station via the one or more network parameters. In some examples, the Device Capture/Registration Table lists each cellular device placed inside the shielded box that undergoes the identification and check in process. In some examples, a user may click a particular entry in the Ran set up table 401 to list the devices captured or devices registered by that particular entry. In some examples, an operator of the identification system may click into an entry on the Device Capture/Registration Table 403 to navigate to a profile UI for the particular cellular device for an entry 405, as will be described in more detail in FIG. 5.

It should be noted that this disclosure is not limited to the specific configuration or any other specific table layout. Instead, the disclosure describes the specific columns and rows embodiment for illustrative purposes only. The RAN set up table 401 and the Device Capture/Registration Table 403 may contain any number of rows, columns, or any other configuration.

FIG. 5 is an example of a check in/check out profile UI according to some embodiments. As shown in example 500, the check in/check out profile UI 501 may list information about an identity of a cellular device, information about the owner of the cellular device, registration information, check in information, or the like.

In some examples, the information about the identity of the cellular device may include a MSISDN 505, IMSI 507, IMEI 509, device type 523, issued device 525, a provider 527, a personal device 529. In some examples, the information about an owner of the cellular device may include an image 511, a company name 512, whether the owner is a trusted profile 541, and whether the owner is authorized for entry 539. In some examples, the checking in and registration information may include a check in time 513, a check out time 515, a time/date in 517 a time date out 519, a device check out warning 521, a device type, profile created by 531, checked in by 533, checked out by 537 and whether the profile has been uploaded to a C2I 535.

In some examples, information about the identity of the cellular device such as the cellular device's electronic identifiers (MSISDN 505, IMSI 507, and IMEI 509) are automatically entered in by the system when creating a profile to prevent any tampering. Since these electronic identifiers are difficult to manipulate or change, they provide the most reliable way to verify the identity of cellular devices.

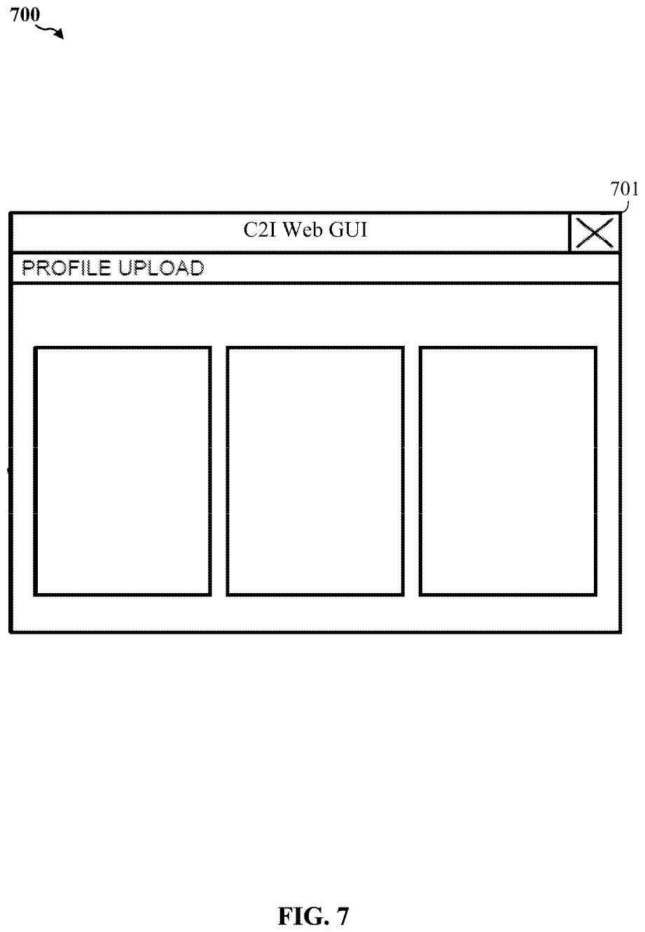

Furthermore, once a profile has been created by an operator, then the profile may be uploaded to a cloud computing system via the “upload to C2I” 535, as will be explained in more detail in FIG. 7.

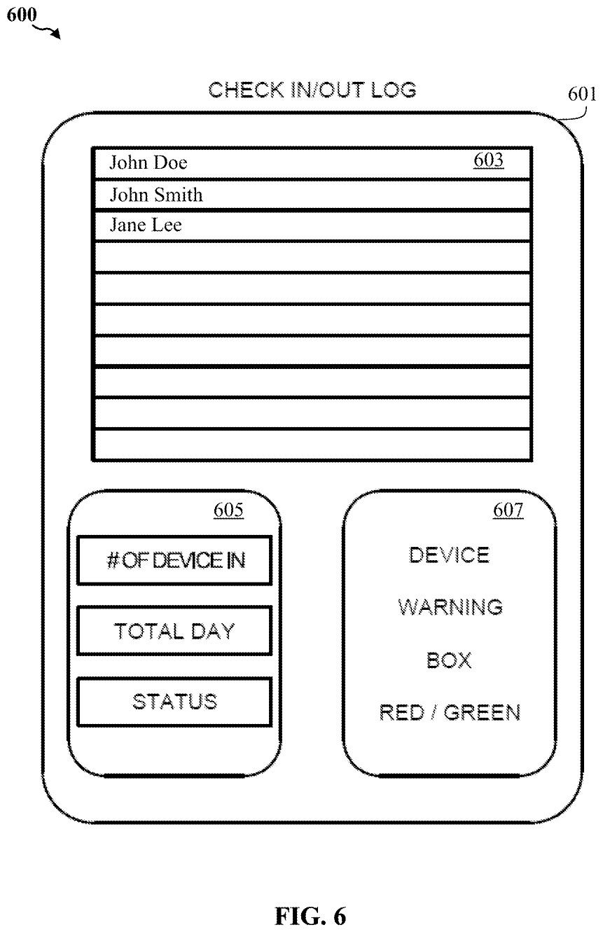

FIG. 6 is an example of a check in/check out log UI according to some embodiments. As shown in example 600, the check in/check out log 601 may provide a list of users or visitors who have checked their cellular devices in 603 into a secured facility, statistics 605 about the number of devices that have been checked in, and an indicator 607 for displaying any warnings or information that can be quickly seen when checking in and checking out cellular devices.

As an example, if a cellular device has been determined as matching a registered profile from a database, then the indicator 607 may display a green light to let an operator know that the cellular device may be checked in. In some examples, the indicator 607 may also display a photo of a user that is registered with the cellular device to allow the operator to ensure that the correct person is checking in (or checking out) a cellular device.

As another example, if a cellular device has been determined as not matching to a registered profile from a database, then the indicator 607 may display a red light to let the operator know that the cellular device is unknown and that a profile for the cellular device may need to be created and registered.

In another example, if the cellular device has been checked in longer than a time period (e.g., more than 10 hours or 24 hours), then the indicator 607 may display a warning to alert the operator.

As another example, the check in/check out log 601 may also be used when checking out a cellular device since an operator will also need to keep track of which cellular devices is leaving a secured facility.

FIG. 7 is an example of a C2I GUI according to some embodiments. As shown in example 700, the C2I Web GUI 701 may pull information from the systems in the fields from the check in/check out log 601 and display respective locations and their activity in real-time. In some examples, the C2I Web GUI 701 may enable an operator to control the devices checked in on the check in/check out log 601 via a C2I system.

It should be noted that this disclosure is not limited to the specific information fields or any other specific UI layout described in FIGS. 4-7. Instead, the disclosure describes the specific UIs are for illustrative purposes only and may contain any other number of information fields, or any other configuration.

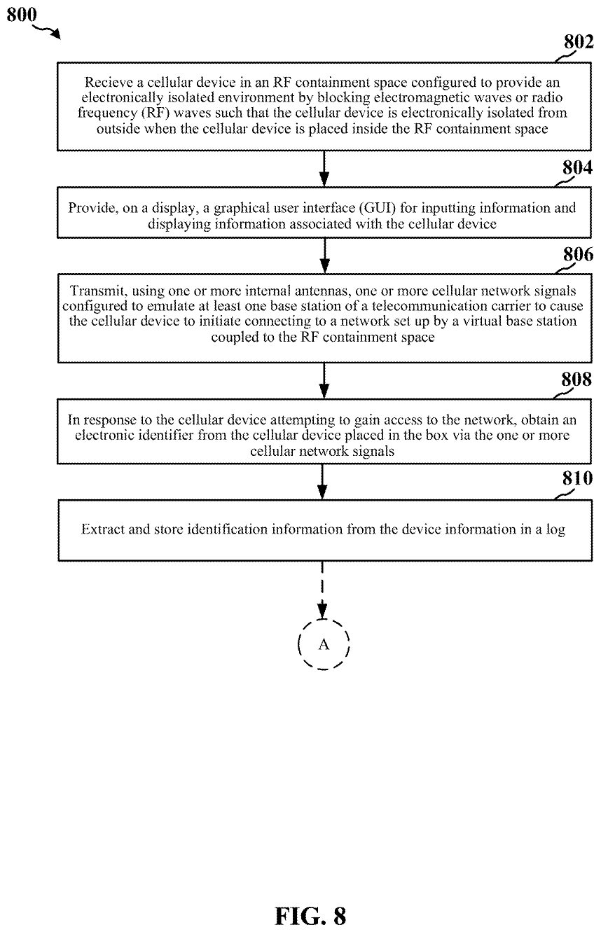

FIG. 8 is flowchart example of an example method of identifying cellular devices using an identification system according to an embodiment. The method 800 may be performed by one or more processor and/or at a base station (e.g., 103, 205) or a virtual base station of an identification system (e.g., 100, 200), another wireless communications apparatus (e.g., the apparatus 1202), or one or more components thereof. Optional aspects are illustrated in dashed lines. According to various different aspects, one or more of the operations in the illustrated methods 800 may be omitted, transposed, and/or contemporaneously performed. This method 800 allows for identification of cellular device by causing the cellular device to transmit an electronic identifier when attempting to connect to a network set up by the base station after the cellular device is placed in a shielded box.

At operation 802, the method 800 may include receiving a cellular device in an RF containment space (e.g., secured box) configured to provide an electronically isolated environment by blocking electromagnetic waves or radio frequency (RF) waves such that the cellular device is electronically isolated from outside the box when the cellular device is placed inside the RF containment space. In some examples, the RF containment space comprises one or more internal antennas. As an example, referring back to FIG. 1, the RF containment space may be a shielded box 101 with one or more internal antennas 111.

At operation 804, the method 800 may include providing, on a display, a GUI for inputting information, displaying information associated with the cellular device, or viewing a log. In some examples, the display may be on another external device.

As an example, referring back to FIGS. 1 and 5, the display 109 may display a profile registration UI 501 with information associated with the cellular device. In some examples, the profile may include at least one of: a photo of a user of the cellular device, a number of the cellular device, a name of the user, a company name for the user, a MSISDN, a IMSI, a IMEI, a trusted device indication, authorized for entry, check in time, check in date, a device check out warning, a device type, a provider, personal device indication, company device indication, profile created by, profile checked in by, or profile checked out by.

As an example, referring back to FIGS. 1 and 6, the display 109 may display a check in/out log 601 with information associated with cellular devices that have been checked in and out by an operator.

At operation 806, the method 800 may include transmitting, using the one or more internal antennas, one or more cellular network signals (e.g., network parameters) configured to emulate at least one base station of a telecommunication carrier to cause the cellular device to attempt to connect to a network set up by the base station when the cellular device is placed in an RF containment space. In some examples, the one or more cellular network signals are determined based on identifying networks in an area of interest.

Placing the cellular device into the RF containment space creates an environment where the cellular device is electronically isolated from electromagnetic waves or RF waves and will cause the cellular device to perform an attach procedure and/or a location update since the box.

In some examples, the one or more cellular signals are transmitted on one or more radio access technologies (RAT) to cause the cellular device to attempt to connect to a network set up by the base station. This means that the one or more cellular signals may transmit on all technologies to cover all RATs.

As an example, referring back to FIGS. 3A-3B, the cellular device will transmit electronic identifiers when attempting to connect to a network provided by the identification system.

The IMEI is a numeric identifier that is unique for 3GPP mobile phones and some satellite phones. GSM networks use the IMEI number to identify valid devices and stop a stolen phone from accessing the network. In particular, an IMEI number may be used as an input for tracking devices that are then able to locate a mobile phone within an accuracy of a few meters.

In some examples, such as in 2G/3G/4G/5G networks, the IMSI may be detected. IMSI comprises country code, wireless provider code, and phone number of the device. In some examples, an IMSI catcher may force the wireless device to respond with its specific location using GPS or the signal intensities of the wireless device's adjacent cell towers, allowing trilateration based on the known locations of the towers.

For example, a 5G registration request message is used by a cellular device to identify itself to the 5G network provided by a base station of the identification system when initiating registration. The registration request message includes the cellular device's IMSI or other unique identifier, such as Temporary Mobile Subscriber Identity (TMSI) or a 5G Globally Unique Temporary Identity (5G-GUTI).

At operation 808, the method 800 may include, in response to the cellular device attempting to gain access to the network, obtaining device information from the cellular device placed in the RF containment space via the one or more cellular network signals. In some examples, the device information may include at least one of IMSI or IMEI.

At operation 810, the method 800 may include extracting and storing identification information from the device information in the log. In some examples, the log may include at least one of a list of a total number of cellular devices check in, check in information, check out information, a duration since the cellular device has been checked in, a status box, or a warning box.

This ensures that there is no tampering from an operator and that the identity of the cellular device may be reliably verified since there the electronic identifiers are difficult to manipulate and there is no manual process of an operator entering any information to remove operator error.

Optionally, at operation 808, the method 800 may identifying networks in an area of interest and decide the best transmissions to transmit inside the RF containment space, wherein the one or more cellular network signals are determined based on the identified networks. The base station 205 may scan the networks periodically to determine whether there has been any changes in the RF footprint for commercial carriers. For example, the scanning process may be performed once a month.

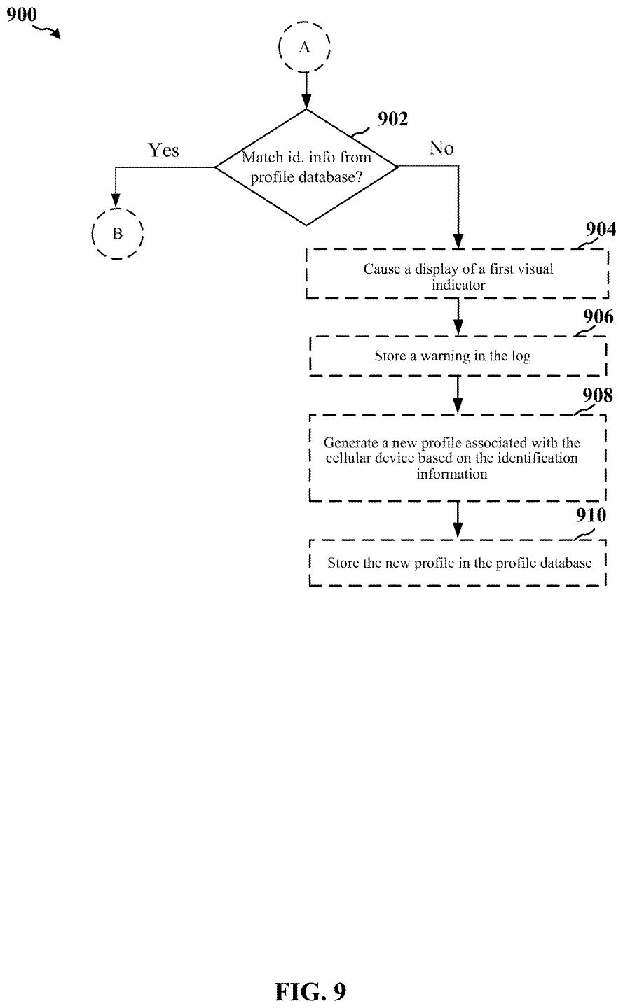

FIG. 9 is flowchart example of an example method of identifying cellular devices using an identification system according to an embodiment. The method 900 may be performed by or at a base station (e.g., 103, 205) of an identification system (e.g., 101, 200), another wireless communications apparatus (e.g., the apparatus 1202), or one or more components thereof. Optional aspects are illustrated in dashed lines. According to various different aspects, one or more of the operations in the illustrated methods 900 may be omitted, transposed, and/or contemporaneously performed. This method 900 includes determining whether the identified cellular device is known or unknown based on comparing the identification information with identification information from a profile database.

As an initial matter, the method 900 continues from operation 810 from FIG. 8, as indicated by a label A.

At operation 902, the method 900 includes determining whether the cellular device matches identification information stored in a profile database.

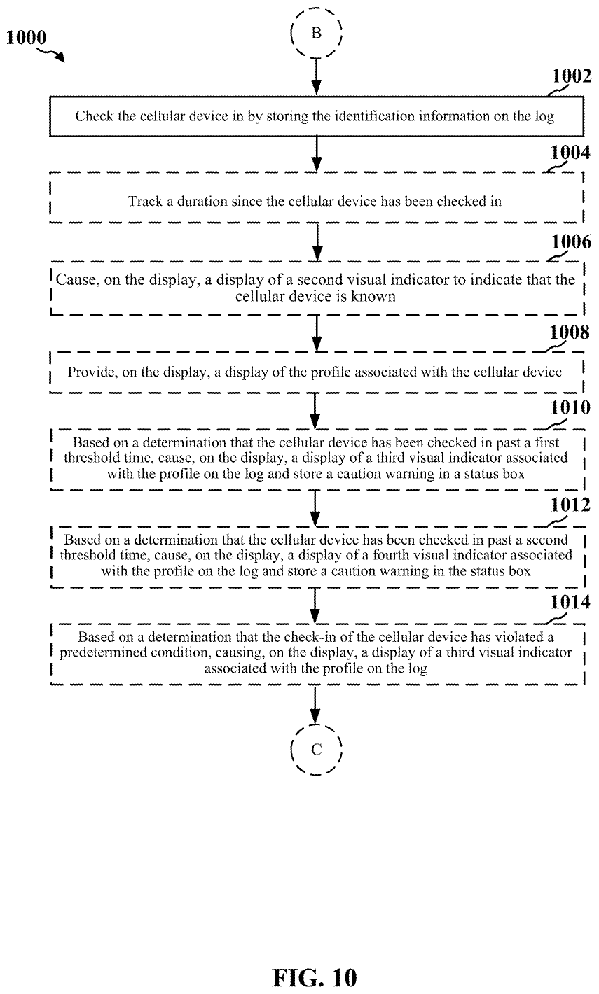

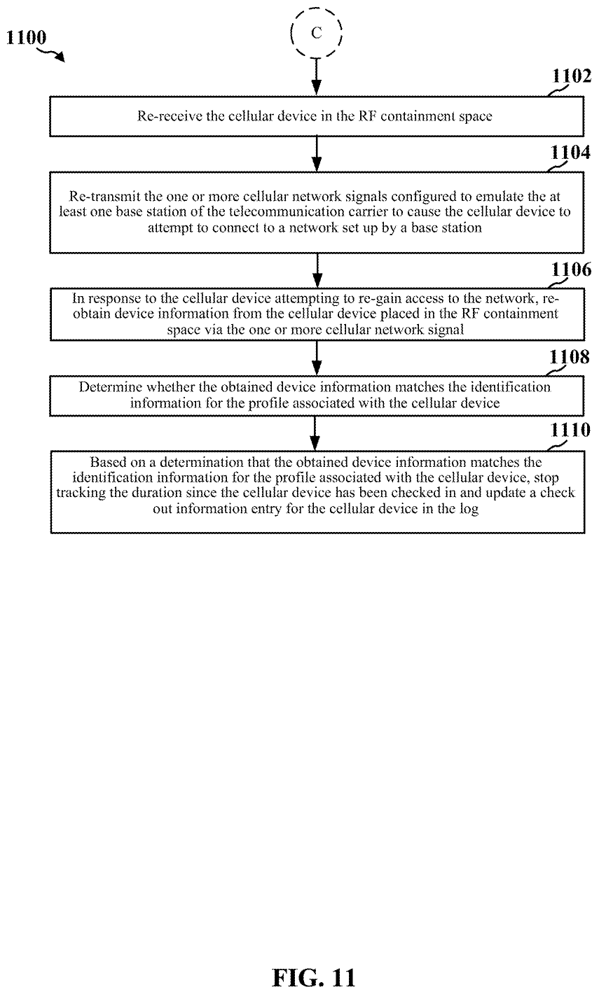

If the determination is yes, then, the method continues to operation 1002 from FIG. 10 (e.g., label B), which will be discussed in more detail in method 1000 and 1100 from FIGS. 10-11.

If the determination is no, then, optionally, at operation 904, the method 900 includes causing a display of a first visual indicator. As an example, referring back to FIG. 6, the check in/out log may display a red light to indicate that the cellular device is not recognized. This allows an operator to easily see that the cellular device has not been previously registered.

Optionally, at operation 906, the method 900 may include storing a warning in the log. As an example, referring back to FIG. 6, the check in/check out log may store a warning that an unrecognized device has been detected.

Optionally, at operation 908, the method 900 may include generating a new profile associated with the cellular device based on the identification information. In some examples, the identification information with the cellular device may be stored in the profile.

As an example, referring back to FIG. 5, the display may provide a profile UI that allows an operator of the identification system to generate a profile for a user of the cellular device. In some examples, the obtained identification information (e.g., MSISDN, IMSI, or IMEI) may be automatically filled in the profile to prevent any tampering or mistakes.

In some examples, the profile may include at least one of: a photo of a user of the cellular device, a number of the cellular device, a name of the user, a company name for the user, a MSISDN, a IMSI, a IMEI, a trusted device indication, authorized for entry, check in time, check in date, a device check out warning, a device type, a provider, personal device indication, company device indication, profile created by, profile checked in by, or profile checked out by. As an example, referring back to FIG. 5, the profile may include at least one of: a photo of a user of the cellular device 511, a number of the cellular device, a name of the user 503, a company name 512, a MSISDN 505, a IMSI 507, a IMEI 509, a trusted device indication 541, authorized for entry 539, check in time 513, check in date 517, a device check out warning 521, a device type 523, a provider 527, personal device indication 529, company device indication 525, profile created by 531, profile checked in by 533, or profile checked out by 537.

In some examples, the method 900 may optionally include logging activity associated with a profile generation process, activity with a check-in procedure, or check-out procedure in an activity log.

This help ensures that an operator is no co-conspiring with a user to smuggle in cellular devices or manipulate profile information for a cellular device. This also creates a log to look back on if there are ever any issues in the check-in/check-out/or registration process.

In some examples, the method 900 may optionally include maintaining synchronization of the profile database, the log, and the activity log with a cloud server.

Optionally, at operation 910, the method 900 may optionally include maintaining synchronization of the profile database, the log, and the activity log with a cloud server. In some examples, the profile database and the log are stored in a local server. In some examples, the profile database and the log are stored in a cloud or local server.

FIG. 10 is flowchart example of an example method of identifying cellular devices using an identification system according to an embodiment. The method 1000 may be performed by or at a base station (e.g., 103, 205) of an identification system (e.g., 101, 200), another wireless communications apparatus (e.g., the apparatus 1202), or one or more components thereof. Optional aspects are illustrated in dashed lines. According to various different aspects, one or more operations of the illustrated methods 1000 may be omitted, transposed, and/or contemporaneously performed. This method 1000 allows for a determination of how long an identified cellular device has been inside a secured facility using an identification system after the cellular device has been recognized and checked-in.

As an initial matter, the method 1000 continues after a determination that the identification information matches identification information from a profile database from operation 902 of FIG. 9, as indicated by B.

At operation 1002, the method 1000 may include checking the cellular device in by storing the identification information on the log. As an example, referring back to FIG. 6, once a cellular device has been verified, then the cellular deice may be logged as an entry 603 in the check-in/check-out log 601.

Optionally, at operation 1004, the method 1000 may include tracking a duration since the cellular device has been checked in. This is done to ensure that the cellular device is not left intentionally or unintentionally inside a secured facility without being properly checked-out. In addition, this also helps manage the number of cellular device that are within a secured facility at any given time.

Optionally, at operation 1006, the method 1000 may include causing, on the display, a display of a second visual indicator to indicate that the cellular device is known. As an example, referring back to FIG. 6, the check in/check out log may display a green indicator in the indicator 607 to indicate that the cellular device is known and checked in. This allows an operator to quickly verify that the cellular device is known and checked-in.

Optionally, at operation 1008, the method 1000 may include providing, on the display, a display of the profile associated with the cellular display. As an example, referring back to FIG. 6, the check in/check out log may display a profile of the user of the cellular device in the indicator 607 to allow the operator to verify that the correct person is checking in with the cellular device.

Optionally, at operation 1010, the method 1000 may include, based on a determination that the cellular device has been checked in past a first time threshold, causing, on the display, a display of a third visual indicator associated with the profile on the log and storing a caution warning in a status box. As an example, the first time threshold may be eight hours may be the length of a typical work day. Accordingly, referring back to FIG. 6, if the cellular device has been checked in past eight hours, then the check-in log may store a caution warning in the indicator 607 by displaying a yellow indicator. As another example, if the cellular device has been checked in past eight hours, then the entry log that corresponds to the checked-in device may be displayed in a yellow indicator on the check-in/check-out log 601.

As another example, if the method 1000, the first threshold may be eight hours, which is the typical length of time of a shift for a correctional officer. Accordingly, if the cellular device is still inside the correctional facility after a length of a typical shift then the cellular device may be flagged as suspicious since this is suspicious behavior. For example, a correctional officer may be attempting to smuggle a cellular device inside for an inmate or an inmate may have stolen the cellular device.

Optionally, at operation 1012, the method 1000 may include, based on a determination that the cellular device has been checked in past a second time threshold, causing, on the display, a display of a fourth visual indicator associated with the profile on the log and store a caution warning in the status box.

As an example, if the method 1000 is being performed in a correctional facility and the second time threshold may be twelve hours. Accordingly, if a cellular device has entered the correctional facility (e.g., checked in), but never checked out, then that would pose a big issue. Accordingly, referring back to FIG. 6, if the cellular device has been checked in past twelve hours, then the check-in log may store a caution warning in the indicator 607 by displaying a red indicator. As another example, if the cellular device has been checked in past twelve hours, then the entry log that corresponds to the checked-in device may be displayed in a red indicator on the check-in/check-out log 601.

Optionally, the method 1000 may include based on a determination that the check-in of the cellular device has violated a predetermined condition, causing, on the display, a display of a third visual indicator associated with the profile on the log. As an example, a predetermined condition may be that the phone cannot be checked in twice without being checked out (e.g., the phone has never checked out and checked in again). Another predetermined condition may be that the phone is not authorized for check in, the phone may only be checked in at certain times, or no phones can be checked in during a particular time period. As yet another example, a predetermined condition may be that the cellular phone being checked in has an electronic identifier that belongs on a banned list. As yet another example, a predetermined condition may be that the cellular phone being check in has an electronic identifier for a staff that has been recently fired or no longer associated with the secured facility.

FIG. 11 is flowchart example of an example method of identifying cellular devices using an identification system according to an embodiment. The method 1100 may be performed by or at a base station (e.g., 103, 205) of an identification system (e.g., 101, 200), another wireless communications apparatus (e.g., the apparatus 1202), or one or more components thereof. Optional aspects are illustrated in dashed lines. According to various different aspects, one or more of the operations in the illustrated methods 1100 may be omitted, transposed, and/or contemporaneously performed. This method 1100 allows for a procedure for checking out a cellular device as a user of the cellular device is leaving a secured facility.

As an initial matter, the method 1100 continues after operation 1014 from FIG. 10 (as indicated by a label C).

At operation 1102, the method 1100 may include re-receiving the cellular device in the RF containment space.

At operation 1104, the method 1100 may include re-transmitting the one or more cellular network signals configured to emulate the at least one base station of the telecommunication carrier to cause the cellular device to attempt to connect to a network set up by a base station.

At operation 1106, the method 1100 may include, in response to the cellular device attempting to re-gain access to the network, re-obtaining device information from the cellular device placed in the RF containment space via the one or more cellular network signal.

At operation 1108, the method 1100 may include determining whether the obtained device information matches the identification information for the profile associated with the cellular device.

For example, if a cellular device has been properly registered and properly checked into the facility, then a user of the cellular device may swap a SIM card or leave a SIM card with an inmate inside the secured facility. Double checking the electronic identifiers of the cellular device as the cellular device leaves the secured facility will prevent this from happening.

At operation 1110, the method 1100 may include, based on a determination that the obtained device information matches the identification information for the profile associated with the cellular device, stop tracking the duration since the cellular device has been checked in, and updating a check out information entry for the cellular device in the log. This verifies that the cellular device (e.g., the correct cellular device) as left a secured facility and is no longer within the facility.

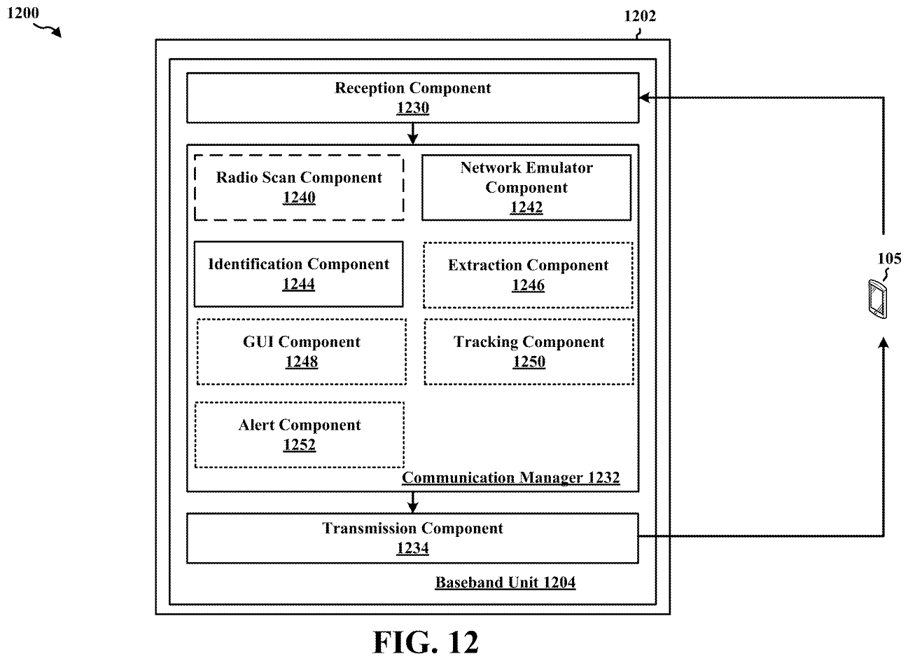

FIG. 12 is a diagram 1200 illustrating an example of a hardware implementation for an apparatus 1202. The apparatus 1202 may include a base station and includes a baseband unit 1204. The baseband unit 1204 may communicate through a cellular RF transceiver with the cellular devices 105, 207, which may include one or more VUEs and/or PUEs. The baseband unit 1204 may include a computer-readable medium/memory. The baseband unit 1204 is responsible for general processing, including the execution of software stored on the computer-readable medium/memory. The software, when executed by the baseband unit 1204, causes the baseband unit 1204 to perform the various functions described supra. The computer-readable medium/memory may also be used for storing data that is manipulated by the baseband unit 1204 when executing software. The baseband unit 1204 further includes a reception component 1230, a radio scan component 1240, a network emulator component 1242, an identification component 1244, an extraction component 1246, a GUI component 1248, a tracking component 1250, an alert component 1252, and a transmission component 1234. The communications manager 1232 includes the one or more illustrated components. The components within the communications manager 1232 may be stored in the computer-readable medium/memory and/or configured as hardware within the baseband unit 1204. The baseband unit 1204 may be a component of the identification system 100 and may include the memory and/or at least one of the TX processor, the RX processor, and the controller/processor.

Optionally, the communications manager 1232 may include a radio scan component 1240 that is configured to identify wireless networks in a radio. The communications manager 1232 also includes a network emulator component 1242 that is configured to cause the box to transmit, using the one or more internal antennas, one or more cellular network signals configured to emulate at least one base station of a telecommunication carrier to cause the cellular device 105 to attempt to connect to a network set up by the base station of an apparatus 1202 when the cellular device 105 is placed in the box, e.g., as described in connection with operation 806 of FIG. 8. The communications manager 1232 also includes an identification component 1244 that is configured to obtain, in response to the cellular device attempting to gain access to the network, an electronic identifier from the cellular device placed in the box via the one or more cellular network signals, e.g., as described in connection with operation 808 of FIG. 8. Optionally, the communications manager 1232 also includes an extraction component 1246 that is configured to extract and store identification information from the device information in a log, e.g., as described in connection with operation 810 of FIG. 8. Optionally, the communications manager 1232 also includes an GUI component 1248 that is configured to provide, on a display, a graphical user interface (GUI) for inputting information and displaying information associated with the cellular device, e.g., as described in connection with operations 804 of FIG. 8. Optionally, the communications manager 1232 also includes a tracking component 1250 that is configured to track a duration since the cellular device has been checked in, e.g., as described in connection with operation 1004 of FIG. 10. Optionally, the communications manager 1232 also includes an alert component 1252 that is configured to cause a status indicator on the box to display visual indicator.

The apparatus may include additional components that perform each of the blocks of the algorithm in the aforementioned flowchart and timing diagram of FIGS. 2 and 8-11. As such, each block in the aforementioned flowchart and timing diagram of FIGS. 2 and 8-11 may be performed by a component and the apparatus may include one or more of those components. The components may be one or more hardware components specifically configured to carry out the stated processes/algorithm, implemented by a processor configured to perform the stated processes/algorithm, stored within a computer-readable medium for implementation by a processor, or some combination thereof.

The benefits of the subject matter claimed herein are immediately apparent. One of many advantages is that the identification system provides a simple and reliable way to verify, register, manage, check in, and check out an identity of cellular devices using their electronic identifiers. This eliminates the need for a contractor to actively monitor and detect wireless devices, as in conventional solutions. In addition, a sophisticated user is also not needed to operate the identification system. This alone can save the facility significant expenditures. No manpower is required (other than deploying the identification system and having an operator operate a simple UI) because an operator of the system simply has to place a cellular device inside of the shielded box and press a button to operate the identification process. In addition, the identification process is reliable and secure because electronic identifiers are difficult to manipulate and falsify.

It is understood that the specific order or hierarchy of blocks in the processes/flowcharts disclosed is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims. Terms such as “if,” “when,” and “while” should be interpreted to mean “under the condition that” rather than imply an immediate temporal relationship or reaction. That is, these phrases, e.g., “when,” do not imply an immediate action in response to or during the occurrence of an action, but simply imply that if a condition is met then an action will occur, but without requiring a specific or immediate time constraint for the action to occur. The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. A method for managing cellular devices comprising:
receiving a cellular device in an RF containment space configured to provide an electronically isolated environment by blocking electromagnetic waves or radio frequency (RF) waves such that the cellular device is electronically isolated from outside when the cellular device is placed inside the RF containment space, wherein the RF containment space comprises one or more internal antennas;
providing, on a display, a graphical user interface (GUI) for inputting information, displaying information associated with the cellular device, or viewing a log;
transmitting, using the one or more internal antennas, one or more cellular network signals configured to emulate at least one base station of a telecommunication carrier to cause the cellular device to initiate connecting to a network set up by a virtual base station coupled to the RF containment space;
in response to the cellular device attempting to gain access to the network, obtaining device information from the cellular device placed in the RF containment space via the one or more cellular network signal; and
extracting and storing identification information from the device information in the log.

2. The method of claim 1, further comprising:
determining whether the cellular device matches identification information stored in a profile database; and
based on a determination that the cellular device does not match identification information stored in the profile database,
generating a new profile associated with the cellular device based on the identification information, wherein the identification information with the cellular device is stored in the profile, and
storing the new profile in the profile database.

3. The method of claim 2, wherein the profile comprises at least one of: a photo of a user of the cellular device, a number of the cellular device, a name of the user, a company name for the user, a MSISDN, a IMSI, a IMEI, a trusted device indication, authorized for entry, check in time, check in date, a device check out warning, a device type, a provider, personal device indication, company device indication, profile created by, profile checked in by, or profile checked out by.

4. The method of claim 1, wherein the device information comprises at least one of an international mobile subscriber identity (IMSI) or an international mobile equipment identity (IMEI).

5. The method of claim 1, further comprising:
determining whether the cellular device matches identification information stored in a profile database, and
based on a determination that the cellular device does not match identification information stored in the profile database,
causing, on the display, a display of a first visual indicator to indicate that the cellular device is unknown.

6. The method of claim 1, further comprising:
determining whether the cellular device matches identification information stored in a profile database, and
based on a determination that the cellular device matches identification information stored in the profile database,
checking the cellular device in by storing the identification information on the log,
providing, on the display, a display of the profile associated with the cellular device,
tracking a duration since the cellular device has been checked in, and
causing, on the display, a display of a second visual indicator to indicate that the cellular device is known.

7. The method of claim 6, wherein checking the cellular device in further comprises:
determine whether a check-in of the cellular device has violated a predetermined condition,
based on a determination that the check-in of the cellular device has violated the predetermined condition, causing, on the display, a display of a third visual indicator associated with the profile on the log.

8. The method of claim 6, further comprising:
based on a determination that the cellular device has been checked in past a first time threshold,
causing, on the display, a display of a third visual indicator associated with the profile on the log, and
storing a caution warning in a status box associated with the cellular device in the log.

9. The method of claim 6, further comprising:
based on a determination that the cellular device has been checked in past a second time threshold,
causing, on the display, a display of a fourth visual indicator associated with the profile on the log, and
storing a warning in a status box associated with the cellular device in the log.

10. The method of claim 6, further comprising:
re-receiving the cellular device in the RF containment space; and
re-transmitting the one or more cellular network signals configured to emulate the at least one base station of the telecommunication carrier to cause the cellular device to attempt to connect to a network set up by a base station;
in response to the cellular device attempting to re-gain access to the network, re-obtaining device information from the cellular device placed in the RF containment space via the one or more cellular network signal;
determining whether the obtained device information matches the identification information for the profile associated with the cellular device; and
based on a determination that the obtained device information matches the identification information for the profile associated with the cellular device,
stop tracking the duration since the cellular device has been checked in, and
updating a check out information entry for the cellular device in the log.

11. The method of claim 10, further comprising:
based on a determination that the obtained device information does not match the identification information for the profile associated with the cellular device,
causing, on the display, a warning, and
storing the warning in the log.

12. The method of claim 1, wherein the log comprises at least one of: a list of a total number of cellular devices check in, check in information, check out information, a duration since the cellular device has been checked in, a status box, or a warning box.

13. The method of claim 2, wherein the profile database and the log are stored in a cloud server.

14. The method of claim 2, further comprising:
logging activity associated with profile generation process, activity with a check-in procedure, or check-out procedure in an activity log, and
maintaining synchronization of the profile database, the log, and the activity log with a cloud server,
wherein the profile database and the log are stored in a local server.

15. The method of claim 1, further comprising:
identifying networks in an area of interest, wherein the one or more cellular network signals are determined based on the identified networks.

16. A system, comprising:
a box configured to provide an electronically isolated environment by blocking electromagnetic waves or radio frequency (RF) waves such that a cellular device is electronically isolated from outside the box when the cellular device is placed in the box, wherein the box comprises one or more internal antennas;
one or more memories containing at least a profile database and a log;
a display; and
one or more processors configured to:
provide, on the display, a graphical user interface (GUI) for inputting information, displaying information associated with the cellular device, or viewing a log;
receive the cellular device in the box;
generate a virtual base station configured to emulate at least one base station of a telecommunication carrier, wherein the virtual base station is coupled to the box;
transmit, using the one or more internal antennas, one or more cellular network signals configured to emulate at least one base station of a telecommunication carrier to cause the cellular device to initiate connecting to a network set up by a virtual base station coupled to the box;
in response to the cellular device attempting to gain access to the network, obtain device information from the cellular device placed in the box via the one or more cellular network signal;
extract and store identification information from the device information in the log.

17. The system of claim 16, wherein the one or more processors are further configured to:
determine whether the cellular device matches identification information stored in a profile database; and
based on a determination that the cellular device does not match identification information stored in the profile database,
generate a new profile associated with the cellular device based on the identification information, wherein the identification information with the cellular device is stored in the profile, and
store the new profile in the profile database.

18. The system of claim 16, wherein the one or more processors are further configured to:
determine whether the cellular device matches identification information stored the profile database, and
based on a determination that the cellular device matches identification information stored in the profile database,
check the cellular device in by storing the identification information on the log,
tracking a duration since the cellular device has been checked in, and
cause, on the display, a display of a second visual indicator to indicate that the cellular device is known.

19. The system of claim 18, wherein the one or more processors are further configured to:
re-receive the cellular device in the box; and
re-transmit the one or more cellular network signals configured to emulate the at least one base station of the telecommunication carrier to cause the cellular device to attempt to connect to a network set up by a base station;
in response to the cellular device attempting to re-gain access to the network, re-obtain device information from the cellular device placed in the box via the one or more cellular network signal;
determine whether the obtained device information matches the identification information for the profile associated with the cellular device;
based on a determination that the obtained device information matches the identification information for the profile associated with the cellular device, stop tracking the duration and update a check out information entry within the log for the cellular device; and
based on a determination that the obtained device information does not match the identification information for the profile associated with the cellular device, causing, on the display, a warning.

20. An apparatus for managing cellular devices comprising:
a box configured to provide an electronically isolated environment by blocking electromagnetic waves or radio frequency (RF) waves such that the cellular device is electronically isolated from outside the box when a cellular device is placed in the box, wherein the box comprises one or more internal antennas;
a display;
a memory configured to store at least a profile database and a log; and
a processing system configured to:
provide, on the display, a graphical user interface (GUI) for inputting information when generating the profile and displaying the profile of the cellular device,
generate a virtual base station configured to emulate at least one base station of a telecommunication carrier, wherein the virtual base station is coupled to the box,
transmit, using the one or more internal antennas, one or more cellular network signals configured to emulate at least one base station of a telecommunication carrier to cause the cellular device to attempt to connect to a network set up by the virtual base station,
in response to the cellular device attempting to gain access to the network, obtain device information from the cellular device placed in the box via the one or more cellular network signal, and
extract and store identification information from the device information in the log.
